(19) United States
(12) Patent Application Publication
(10) Pub. No.: US 2009/0040721 A1
(43) Pub. Date: Feb. 12, 2009

(54) COMPUTER COOLING SYSTEM AND METHOD

(75) Inventor: GEOFF SEAN LYON, Calgary (CA)

Correspondence Address: BENNETT JONES LLP;C/O MS ROSEANN CALDWELL, 4500 BANKERS HALL EAST, 855 - 2ND STREET, SW, CALGARY, AB, T2P 4K7, CA

(73) Assignee: COOLIT SYSTEMS INC., Calgary (CA)

(21) Appl. No.: 12/188,065

(22) Filed: Aug. 7, 2008

Related U.S. Application Data
(60) Provisional application No. 60/954,493, filed on Aug. 7, 2007.

(51) Int. Cl. H05K 7/20

(52) U.S. Cl. 361/697

(57) ABSTRACT

A method for providing a computer component includes providing a motherboard apart from a cooling solution such that the end user can select the motherboard and cooling solution separately, based on preferences and needs for each and connect them together after they are selected. To support this method, a motherboard includes: a support board; a chipset mounted on the support board; and a heat sink base mounted over the chipset, the heat sink base including an open, planar upper surface devoid of any cooling system working components pre-installed thereon but including a fastener aperture about the edge of the open, planar upper surface and in addition to any support board mounting connections, the fastener aperture formed to accept releasable connectors for securing the selected cooling working component.

### FIELD

The present invention is directed to an electronics cooling system and method, such as those for a computer.

### BACKGROUND

A motherboard and a video card are two examples, in a modern computer, of printed circuit boards often including a plurality of chip sets and other heat generating devices. Many motherboards, for example, include a Northbridge chipset, a Southbridge chipset, integrated circuits, voltage regulators, etc. In modern computers, the chipsets and other components increasingly operate at higher speeds.

Using the chipsets as an example, the Northbridge chipset connects the high speed components including for example, those for main memory and graphics functionalities, while the Southbridge chipset connects to the lower speed peripheral devices. The higher operation speeds now commonly sought, causes the Northbridge, and in some cases the Southbridge, chipsets to generate problematic thermal energy.

To alleviate the adverse effects of thermal energy, it is now common for cooling systems to be provided for the chipsets and sometimes for other components. Often a cooling system is pre-installed and sold with the board. However, because of the various cooling options available board manufacturers are faced with the problem of offering a plurality of different models of boards with similar circuitry but each with a different cooling option to satisfy the array of consumers.

### SUMMARY

In one aspect of the invention there is provided a method for providing a circuit board with a cooling solution comprising: providing a circuit board including a heat generating component and a heat sink base installed over the heat generating component; providing a cooling system working component including at least one of (i) an air cooling mechanism and (ii) a liquid cooling mechanism; and connecting the cooling system working component to the heat sink base for operation.

In another aspect there is provided a circuit board comprising: a support board; a heat generating component mounted on the support board; and a heat sink base mounted over the heat generating component, the heat sink base including an open, planar upper surface with an edge thereabout, support board mounting connections securing the heat sink base to the support board and a mounting site about the edge of the open, planar upper surface in addition to the support board mounting connections, the mounting formed to accept releasable connectors.

In another aspect there is provided a computer circuit board comprising: a support board; a heat generating component mounted on the support board; and a heat sink base mounted over the heat generating component, the heat sink base including an open, planar upper surface devoid of any cooling system working components installed thereon prior to sale thereof and including a mounting site adjacent the open, planar upper surface and in addition to any support board mounting connections, the mounting site formed to secure a selected cooling working component to the heat sink base.

It is to be understood that other aspects of the present invention will become readily apparent to those skilled in the art from the following detailed description, wherein various embodiments of the invention are shown and described by way of illustration. As will be realized, the invention is capable for other and different embodiments and its several details are capable of modification in various other respects, all without departing from the spirit and scope of the present invention. Accordingly the drawings and detailed description are to be regarded as illustrative in nature and not as restrictive.

### BRIEF DESCRIPTION OF THE DRAWINGS

Referring to the drawings wherein like reference numerals indicate similar parts throughout the several views, several aspects of the present invention are illustrated by way of example, and not by way of limitation, in detail in the figures, wherein:

FIG. 1 is an exploded, perspective view of a system according to one embodiment of the invention;

FIGS. 2A, 2B and 2C are exploded, perspective, and top plan views, respectively, of a system according to another embodiment of the invention; and

FIG. 3 is a perspective view of a motherboard packaged for distribution.

### DESCRIPTION OF VARIOUS EMBODIMENTS

The detailed description set forth below in connection with the appended drawings is intended as a description of various embodiments of the present invention and is not intended to represent the only embodiments contemplated by the inventor. The detailed description includes specific details for the purpose of providing a comprehensive understanding of the present invention. However, it will be apparent to those skilled in the art that the present invention may be practiced without these specific details.

A cooling system for a circuit board may operate to cool one or more of various heat generating components on the board. Circuit boards may include, but are not limited to, motherboards and video cards. As will be appreciated, these types of boards include various components that generate heat and that are sometimes sought to be cooled such as, for example, chipsets for processing and/or memory (GPU, CPU, RAM, Northbridge, Southbridge, etc.), integrated circuits of various kinds (IC, ASIC, etc.), voltage regulators, etc.

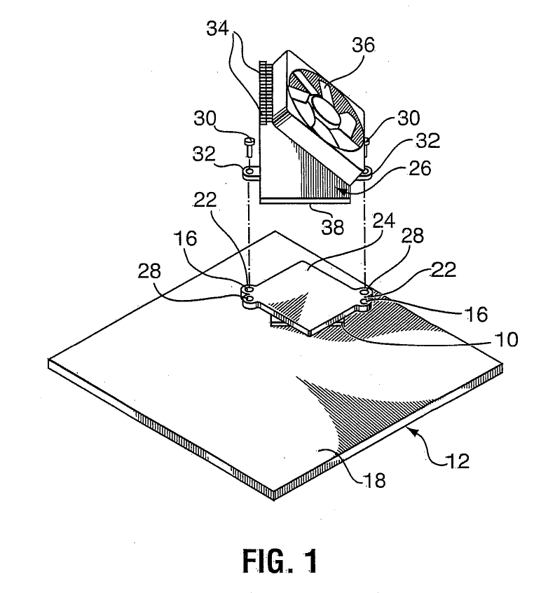

With reference to FIG. 1, a cooling system for a heat generating component such as a chipset 10 on a circuit board such as board 12 (i.e. a video card board or motherboard) may include a heat sink base 14 mounted over the chipset. The chipset may be any of the various chipsets on a board, such as in a computer application, those for memory and/or processing such as the Northbridge or the Southbridge chipsets.

The heat sink base acts as a foundation for a cooling system working component to be separately provided and installed on the base or provided in one form and easily switched out while the base acts as a protective barrier over the more delicate components of the board. Base 14 may include an open, planar upper surface 24 forming a support surface for a cooling system working component 26 to be installed thereon. The open planar upper surface may be formed on a solid plate, with an opposite side thereof in thermal communication with the surface of the heat generating component. Alternately, as shown in later Figures, the open planar upper surface may be formed on a plate with an opening therethrough through which either a portion of a cooling system working component may extend to contact a surface of a heat generating surface of the chip set or a portion of the chipset may extend to be at a level substantially even with planar surface 24.

The heat sink base may include mounting connections through which it is secured to the support board 18 of the board. Such support board mounting connections may include fasteners, bolts, screws, solder, pins, rivets, staples, adhesives, clips, clamps, etc. that firmly secure the base to the board's support board 18. In the illustrated embodiment, the heat sink base is secured to board 18 by two pinned connections including pins 16 extending between the support board and mount sites 22 including apertures on the base. Base 14 serves as a foundation for installation of cooling system working component 26. Base 14 can be formed in a universal fashion to accept various types of working components. As such, base 14 can be formed such that it is permanently mounted to support board 18. For example, if desired, pins 16 may be permanently installed and removable only with significant force or by destruction of the pins, the base or the support board.

Since base 14 acts as a foundation to support a working component, the base itself can be devoid of any cooling system working components. For example, the base need not include any pre-installed fans or liquid cooling systems and the base itself need not be powered.

Heat sink base 14 may further include one or more fastener apertures 28 formed about an edge of the open, planar upper surface. In the illustrated embodiment, two fastener apertures 28 are provided, formed in addition to and apart from board mounting connections 16, 22. Fastener apertures 28 are formed to accept connectors 30 such as pins, fasteners, springs, clips, clamps, etc. that connect the working component to the base. Connectors 30 may or may not be removable after installation thereof.

Cooling system working component 26 may include a lower surface with a thermal/mechanical integrity selected to correspond to the form of heat sink base 14. For example, the cooling system working component can have one or more of a size, a shape, a clearance, a mounting configuration, selected to correspond to those features of the heat sink base to allow aligned installation and thermal transfer of the working component on the base. In one embodiment, the component's lower surface is substantially the mirror image of the base in respect of its mating surface shape, including perimeter shape and surface contour, size and mounting configuration, including location of its mounting sites. Cooling system working component 26 may, therefore, include a lower surface formed (shaped and sized) to fit on upper surface 24 of heat sink base 14 and with mounting sites 32 positioned and sized for alignment with and cooperation with apertures 28 on base 14. As such, the universal form of base 14 can be considered in the production of components 26 for installation thereon such that regardless of the cooling technology offered by the cooling system working component, that component can be quickly, easily and correctly installed on the base without much risk of damage to other board components since, as in the illustrated embodiment, connection of the working component for operation can be achieved by connection of connectors to the base rather than directly to the support board.

Component 26 may take various forms with respect to its cooling technology. For example, the component may include heat sink fins 34 and/or a fan 36, as shown, to act in the dissipation of thermal energy received through heat spreader plate 38. Alternately or in addition, a component may include a liquid cooling technology, as shown in later Figures.

In such an embodiment, board 12 may be manufactured and distributed with a heat sink base installed over at least one of its heat generating components. Such an approach may offer a user, such as an oem (original equipment manufacturer), a system integrator, and/or a retail consumer, the ability to select a board of interest and then also and separately select a cooling system working component of interest for mounting on the heat sink base. In this way, the board is ready for easy installation of a cooling system working component that is formed to fit thereon and is of interest to the user. The cooling system working component can be installed easily using connectors intended to install through existing connection sites 28 and without modification of or removal of preinstalled cooling system working components (fans, liquid cooling systems, etc.) from the board.

To obtain a board with a cooling system, the user may (i) select a board including a heat sink base installed over at least one of its chipsets, (ii) select a cooling system working component formed for installation on the heat sink base and (iii) install the cooling component on the heat sink base. Installation may include application of a thermal paste between the working component lower surface and the base upper surface, or the exposed heat generating component where there is an opening through the base upper surface, positioning the lower surface of the cooling component onto the upper open surface such that the lower surface is in thermally conductive communication with the upper open surface, or a chipset surface, securing the cooling component onto the base, as by aligning apertures 32, 28 on the base and the component, installing connectors 30 therethrough and connecting electrical supply lines between the working component and the board, as by use of plugs and sockets. In one embodiment, the board selected will have no cooling fans, liquid cooled systems or other elaborate cooling components over the chipset and, as such, the user will not be required to remove any such cooling components prior to installation of the selected cooling system working component. This facilitates manufacture and distribution and avoids waste of undesired components. This may also avoid board damage during installation of the cooling system working component.

A computer cooling system can be provided, therefore, by providing a board including a heat generating component thereon and a heat sink base installed over the heat generating component and providing a cooling system working component including at least one of (i) an air cooling mechanism and (ii) a liquid cooling mechanism. One or more manufacturers and/or distributors can provide these components by offering, selling or giving them to a user separately, in kits, etc. The marketing and/or packaging can separate the board from the cooling system working component so that each can be selected independently depending on the user's needs or preferences for each. The packaging or product display, offering, instructions or specifications can inform the user that they must select one of each of the board and the cooling system working component. Thereafter, the cooling system working component can be connected to the heat sink base for operation of the cooling system. Instructions and installation supplies such as, for example, connectors 30 and paste may be provided with each or one of the board and the working component.

The heat sink base 14 and the working component can be formed to fit together. For example the shapes of the base planar surface 24 and the working component's lower surface and the locations of mounting sites 28, 32 about the surfaces can be selected such that the parts fit together easily and in a universal fashion such that, regardless which of the offered working components are selected, they can be installed easily onto the base, while the base remains attached to support board 18.

Of course, if the board manufacturer, which may be one or more entities, so desires, the board can be produced and distributed with a cooling system working component mounted on the base. This may be the desired approach where the manufacturer does not wish to distribute a product that is not ready for use. As will be appreciated, for example, this may be done to avoid confusion, inconvenience or accidental use without an operative cooling solution. In such a case, a board may be provided that includes a base mounted over a heat generating component, the base having a selected and known form, and a cooling system working component releasably installed on the base, the working component formed with consideration as to the selected and known form of the base but which is releasable from the base without damaging the board, the functional components of the board or the base. Such a provided working component, may be of a basic, lower cost form suitable for general use. As such, a user, such as an oem, a system integrator or a retail consumer, could use (i.e. employ, install, resell, etc.) the board with the provided cooling system working component or can replace the provided cooling system working component with a selected cooling system working component. If the consumer chooses to switch out the provided working component, the provided cooling system working component can be removed, as by removing connectors 30 and, thereafter, another selected cooling system working component could be installed on the base. In one embodiment, a variety of cooling system working components could be provided with universal lower surfaces formed to correspond to the universal features of the base such that any of the variety of cooling system working components could be selected and installed on the base.

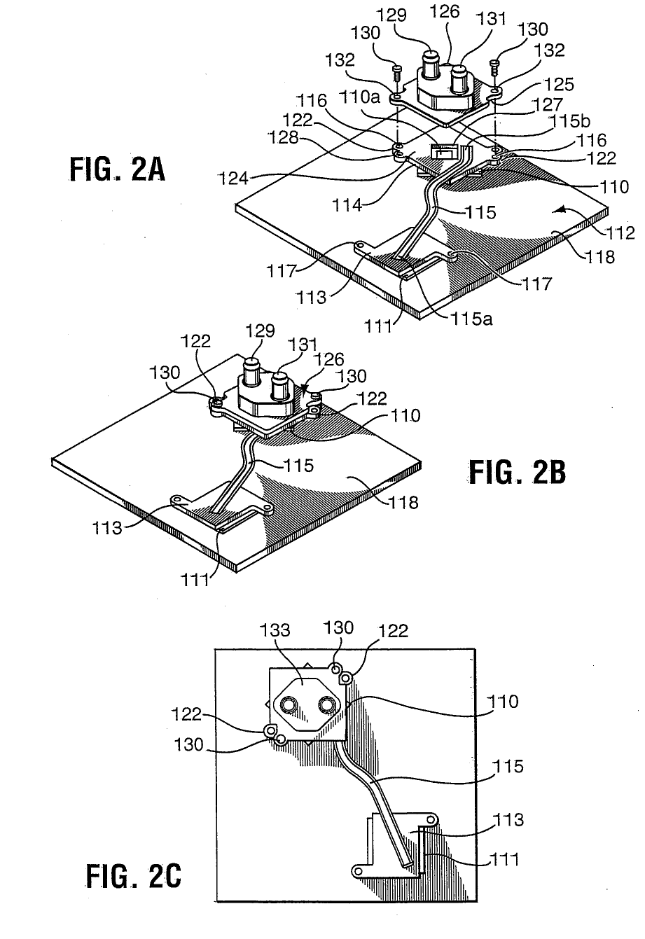

With reference to FIG. 2, a circuit board such as motherboard 112 may include more than one heat generating component. For example, a motherboard may include a Northbridge chipset 110 and a Southbridge chipset 111. To address issues of complexity, space, etc. it may be useful to provide a cooling system for the motherboard that connects and shares components between the chipsets. For example, a cooling system may include a heat sink 113 on one of the chipsets and a heat sink base 114 mounted over another chipset. The heat sink 113 and heat sink base 114 may be thermally connected by a heat pipe 115 to convey thermal energy from the heat sink to the heat sink base. Heat pipe 115 includes an evaporator portion 115a thermally coupled to heat sink 113 and a condenser portion 115b thermally coupled to heat sink base 114. It will be appreciated that a heat pipe operates by phase change of a heat transfer, working medium between the heat pipe's evaporator portion 115a and condenser portion 115b. Heat pipes generally include a closed envelope in which heat transfer working medium is contained. The heat transfer is achieved by vaporization of the working medium at the evaporator portion by action of received thermal energy and condensation of the gaseous working medium at the condenser portion, which is cooler due to its thermally conductive contact with a component that permits dissipation of the thermal energy. A circuit is set up within a heat pipe wherein working medium returns from the condenser portion to the evaporator portion by gravity flow or wicking action. In the illustrated embodiment, heat sink 113 is non-working, only operating to conduct thermal energy from its chipset to evaporation portion 115a of the heat pipe. Heat sink base 114 is configured to accept a working component 126 to actively dissipate heat from chipset 110 and from the heat pipe 115. Other heat sinks and heat pipes may extend from other heat generating components to the heat sink base 114, as desired.

In one embodiment as shown, heat sink base 114 may be positioned over the component with the greatest thermal output, such as the Northbridge chipset. This arrangement of components may be useful as the Northbridge chipset generally exhibits more thermal generation than the Southbridge chipset and the Southbridge chipset has less space available about it.

Heat sink 113 and heat pipe 115 may be installed prior to distribution to the user, for example may be factory installed and then distributed to oems, system integrators and/or retail consumers. Heat sink 113, for example, may be secured over its chipset by connectors 117 engaging the motherboard support board 118.

Heat sink base 114 may also be pre-installed, for example during manufacture or at least prior to sale to the retail consumer, for example, including motherboard mounting connections, including one or more of fasteners, bolts, screws, solder, pins, rivets, staples, adhesives, clips, clamps, etc., that firmly secure the base to board 118. In the illustrated embodiment, the heat sink base is secured to board 118 by two connections including fasteners 116 extending through mounting sites 122 including apertures on the base, the fasteners then passing into engagement with the board.

The heat sink base may include an open, planar upper surface 124 forming a support surface for a cooling system working component 126 to be releasably installable thereon. The open planar upper surface may include an opening 127 therethrough through which a portion of a cooling system working component may extend to contact a heat generating surface 110a of the chipset or a portion of the chipset may extend to a position substantially flush with the upper surface 124. In such an embodiment, the heat sink base may conduct heat from any chipset components with which it is in contact and from condenser portion 115b of the heat pipe to working component 126, while working component 126 also directly accepts thermal energy from surface 110a of the chipset with which it is in direct contact. As noted previously, heat sink base 114 may alternately have a solid upper surface with an opposite side thereof in thermal communication with the surface of a heat generating component of the chipset over which it is mounted.

Heat sink base 114 may further include one or more connection sites such as fastener apertures 128 formed about the open, planar upper surface. In the illustrated embodiment, two fastener apertures 128 are provided, formed apart from motherboard mounting connections 116, the fastener apertures formed to accept connectors 130 such as pins, fasteners, bolts, screws, rivets, springs, clips, clamps, etc. that connect the working component to the base. Connectors 130 may or may not be removable.

Cooling system working component 126 includes a lower surface 125 formed to fit on upper surface 124 of heat sink base 114, a protrusion (cannot be seen in any view) extending down from lower surface 125 and sized to extend down through opening 127 and mounting sites 132 for alignment with and cooperation with apertures 128. Features of the lower surface of working component such as, for example, perimeter shape, surface contour, size, clearance, position of sites 132, and position of the protrusion can be selected to correspond to those features of the base such that any such lower surface can easily and properly install over and thermally operate with the base.

Component 126 may take various forms for example, with respect to its cooling technology. For example, the component may include a liquid block portion 133 including a liquid inlet 129 and a liquid outlet 131. As noted previously, a component may alternately include an air cooling technology. A range of working component may be available with liquid or air cooling solutions each with a selected power rating and cooling capability.

In such an embodiment, motherboard 112 may be distributed to a user with a heat sink base installed over at least one of its chipsets and a heat pipe connection to another heat sink. Such a motherboard may offer a user the ability to select a motherboard of interest and then also and in common packaging or separately, select a cooling system working component of interest for mounting on the heat sink base. In this way, the motherboard is ready for easy installation of a cooling system working component of interest to the consumer. The cooling system working component can be installed easily using connectors intended to install at existing connection sites on the base and sometimes without modification or removal of pre-installed cooling system working components on the motherboard. By providing a heat sink base with a universal form and offering a variety of cooling system working components that are formed to correspond to the universal form of the heat sink base, the heat sink base can be installed on the motherboard, and the motherboard can be manufactured and stocked, in a condition ready for installation of a cooling system component of interest and selected by the user.

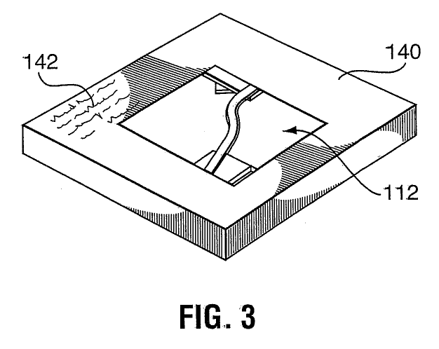

To obtain a motherboard with a cooling system thereon, the end user may follow the above-noted method except that the motherboard selected may include a heat sink base installed over one of its chipsets, a heat sink installed over another of its chipsets and a heat pipe connected therebetween. The packaging, instructions, specification, product display or product offering can inform the user that they must select one of each of the motherboard and the cooling working component. For example, as shown in FIG. 3, a circuit board 112 may be offered in packaging 140 that includes instructions 142 thereon or therein that a cooling system working component must be obtained separately. The cooling system working component can also be packaged with similar instructions.

The previous description of the disclosed embodiments is provided to enable any person skilled in the art to make or use the present invention. Various modifications to those embodiments will be readily apparent to those skilled in the art, and the generic principles defined herein may be applied to other embodiments without departing from the spirit or scope of the invention. Thus, the present invention is not intended to be limited to the embodiments shown herein, but is to be accorded the full scope consistent with the claims, wherein reference to an element in the singular, such as by use of the article “a” or “an” is not intended to mean “one and only one” unless specifically so stated, but rather “one or more”. All structural and functional equivalents to the elements of the various embodiments described throughout the disclosure that are know or later come to be known to those of ordinary skill in the art are intended to be encompassed by the elements of the claims. Moreover, nothing disclosed herein is intended to be dedicated to the public regardless of whether such disclosure is explicitly recited in the claims. No claim element is to be construed under the provisions of 35 USC 112, sixth paragraph, unless the element is expressly recited using the phrase “means for” or “step for”.

I claim:

1. A method for providing a circuit board with a cooling solution comprising: providing a circuit board including a heat generating component and a heat sink base installed over the heat generating component; providing a cooling system working component including at least one of (i) an air cooling mechanism and (ii) a liquid cooling mechanism; and connecting the cooling system working component to the heat sink base for operation.

2. The method of claim 1 wherein providing includes selling.

3. The method of claim 1 wherein providing a cooling system working component includes offering the cooling system working component in packaging enabling selection by a user.

4. The method of claim 3 wherein providing a circuit board includes packaging the circuit board for selection by the user apart from the packaging of the cooling system working component.

5. The method of claim 3 wherein the user is selected from the group consisting of an original equipment manufacturer, a system integrator and a retail consumer.

6. The method of claim 1 wherein providing a cooling system working component includes allowing a selection of at least one cooling mode of operation from an air cooling technology and a liquid cooling technology.

7. The method of claim 1 wherein the heat sink base includes an open, planar upper surface with a selected mounting configuration and the cooling system working component includes a lower surface with a mounting site correspondingly positioned relative to the mounting configuration and connecting the cooling system working component includes aligning the mounting site with the mounting configuration and securing the mounting site to the mounting configuration.

8. The method of claim 1 wherein the circuit board when provided is devoid of cooling system working components installed over the heat generating component.

9. The method of claim 1 wherein connecting proceeds without first removing an existing cooling system working component from the heat sink base.

10. The method of claim 1 wherein the circuit board when provided includes a pre-installed cooling system working component releasably connected on the heat sink base.

11. The method of claim 1 wherein prior to connecting, the method further comprises removing a provided cooling system working component from the heat sink base.

12. The method of claim 1 wherein providing a cooling system working component includes selection by a user, providing a circuit board includes selection by the user and connecting is conducted by the user.

13. The method of claim 1 wherein connecting includes using instructions provided with at least one of the cooling system working component and the circuit board.

14. A circuit board comprising: a support board; a heat generating component mounted on the support board; and a heat sink base mounted over the heat generating component, the heat sink base including an open, planar upper surface with an edge thereabout, support board mounting connections securing the heat sink base to the support board and a connection site about the edge of the open, planar upper surface in addition to the circuit board mounting connections, the connection site formed to accept releasable connectors.

15. The circuit board of claim 14 devoid of any factory installed cooling system working components for the heat generating component.

16. The circuit board of claim 14 in packaging for sale of the circuit board, the packaging containing no cooling system working components for the heat generating component.

17. The circuit board of claim 14 in packaging for sale of the circuit board, the packaging including an instruction that a separate cooling system working component is required for the circuit board.

18. The circuit board of claim 14 wherein the heat sink base includes an aperture on the open, planar upper surface such that a portion of the heat generating component is directly accessible therethrough.

19. The circuit board of claim 14 further comprising: a second heat generating component; a heat sink heat conducting plate installed over the second heat generating component and a heat pipe connecting between the heat sink heat conducting plate and the heat sink base.

20. The circuit board of claim 14 in the form of a video card.

21. The circuit board of claim 14 in the form of a motherboard.

22. A computer circuit board comprising: a support board; a heat generating component mounted on the support board; and a heat sink base mounted over the heat generating component, the heat sink base including an open, planar upper surface devoid of any cooling system working components installed thereon prior to sale thereof and including a mounting site adjacent the open, planar upper surface and in addition to any support board mounting connections securing the heat sink base to the support board, the mounting site formed to secure a selected cooling system working component to the heat sink base.

23. The computer circuit board of claim 22 in packaging for sale thereof, the packaging containing no cooling system working component for the heat generating component.

24. The computer circuit board of claim 22 in packaging for sale of the circuit board, the packaging including an instruction that the selected cooling system working component is required for use with the circuit board.

25. The computer circuit board of claim 22 further comprising instructions and supplies for mounting the selected cooling system working component to the heat sink base.

26. The computer circuit board of claim 22 wherein the heat sink base includes an aperture on the open, planar upper surface such that a portion of the heat generating component is directly accessible therethrough.

27. The computer circuit board of claim 22 further comprising: a second heat generating component; a heat sink heat conducting plate installed over the second heat generating component and a heat pipe connecting between the heat sink heat conducting plate and the heat sink base.
